(19) United States
(12) Patent Application Publication
(10) Pub. No.: US 2016/0011272 A1
(43) Pub. Date: Jan. 14, 2016

(54) ESTIMATION METHODS AND DEVICES FOR STATE-OF-CHARGE OF BATTERIES

(71) Applicant: MediaTek Singapore Pte. Ltd., Singapore (SG)

(72) Inventor: Mingming ZHANG, Hefei City (CN)

(21) Appl. No.: 14/791,724

(22) Filed: Jul. 6, 2015

(30) Foreign Application Priority Data
Jul. 9, 2014 (CN) 201410325574.6

(51) Int. Cl. G01R 31/36

(52) U.S. Cl. CPC G01R 31/3651; G01R 31/3665; G01R 31/3606

(57) ABSTRACT

An estimation device and method are provided. A battery measurement platform sets up a communication with a measured battery, determines a model of the measured battery, and searches data of the measured battery according to the model thereof to obtain the state-of-charge of the measured battery. Accordingly, the estimation of the state-of-charge of batteries is performed on base of each battery, instead of on base of each battery measurement platform.

### CROSS REFERENCE TO RELATED APPLICATIONS

This application claims priority of China Patent Application No. 201410325574.6, filed on Jul. 9, 2014, the entirety of which is incorporated by reference herein.

### BACKGROUND OF THE INVENTION

1. Field of the Invention

The invention relates to a field of power supplying from batteries, and more particularly to an estimation method and device for state-of-charge of batteries.

2. Description of the Related Art

Batteries (including non-rechargeable batteries and rechargeable batteries) are widely used in many applications. For example, batteries can be applied in electric vehicles, portable apparatuses, wearable apparatuses, and other mobile apparatuses.

State-of-charge of batteries is an important physical quantity, which allows users to know the remaining power quantity impersonally. In current technique, there are many manners to estimate state-of-charge of batteries for mobile apparatuses. The current manners to estimate state-of-charge of batteries include performing a sample collection with different loading for batteries by using professional apparatuses, such as BAT 760, or performing discharging quantity by using fuel gauges to obtain remaining power, wherein, Coulomb counting and open-loop voltage measurement are applied for operation. However, the above manners have some limitation:

1) The data obtained from the load test is applied to measurer battery capacity and discharge curve only in a specific load.

2) The external interference variables adopted by the test data are suffered by discrete valued difference analysis algorithm. For example, the battery is tested respectively at 0 degree, 25 degrees, and 50 degrees, the obtained test data are discrete. Accordingly, there is operation error, which causes an inaccurate measured result.

Moreover, the current battery measurement platform is dedicated to specific batteries. The maintain and measurement of the batteries is performed for each battery measurement platform. Thus, battery data is built for each battery measurement platform. In the case that different battery measurement platforms are used for the same battery, a data input operation is still performed even though the battery feature curve is independent experiment data which is not related to the specific printed circuit board (PCB).

### BRIEF SUMMARY OF THE INVENTION

The prevent invention provides an estimation method and device for estimating state-of-charge of batteries. The estimation of the state-of-charge of the batteries is performed per-battery, which ensures accurate measurement results, random battery change, and convenient maintaining.

An exemplary embodiment of an estimation method is provided. The estimation method comprises steps of setting up a communication with a measured battery by a battery measurement platform; determining a model of the measured battery by the battery measurement platform; and searching data of the measured battery according to the model of the measured battery by the battery measurement platform to obtain state-of-charge of the measured battery.

In an embodiment, the step of determining the model of the measured battery comprises steps of determining the model of the measured battery through an identification circuit and receiving the model of the measured battery through a multimedia interface when determining the model of the measured battery through the identification circuit is not successful.

In another embodiment, the step of searching data of the measured battery according to the model of the measured battery comprises a step of automatically finding the data of the measured battery from a database according to the model of the measured battery.

In further another embodiment, the data of the measured battery is stored in the database and not dedicated to the battery measurement platform, and the database comprises data of batteries with at least two models.

In an embodiment, the data of the batteries with one of the least two models is received from a cloud system.

In another embodiment, the data of the batteries with one of the least two models is input through a multimedia interface.

In further another embodiment, the data of the measured battery is corrected and updated through a cloud system.

In an embodiment, the corrected and updated data of the measured battery from the clod system is generated according to actual data of the measured battery in different loads.

In another embodiment, the data of the measured battery comprises the model of the measured battery and a feature curve data matching the measured battery, and the feature curve data comprises mapping relationship between internal resistance and voltage or temperature, mapping relationship between a voltage and capacity, and data variation between additional data and cycle life.

An exemplary embodiment of an estimation device is provided. The estimation device comprises a connection module, a model obtaining module, and a detection module. The connection module is configured to setting up a communication between the battery measurement platform and a measured battery. The model obtaining module, coupled to the connection module, is configured to determine a model of the measured battery. The detection module, coupled to the model obtaining module, is configured to search data of the measured battery according to the model of the measured battery to obtain state-of-charge of the measured battery. In an embodiment, the model obtaining module determines the model of the measured battery through an identification circuit and loads the model of the measured battery when the model of the measured battery is determined unsuccessful.

In another embodiment, the detection module automatically searches the data of the measured battery from a database according to the model of the measured battery.

In further another embodiment, the estimation device further comprises an update module. The update module corrects and updates the data of the measured battery through a cloud system.

In another embodiment, the data of the measured battery comprises the model of the measured battery and a feature curve data matching the measured battery, and the feature curve data comprises mapping relationship between internal resistance and voltage or temperature, mapping relationship between a voltage and capacity, and data variation between additional data and cycle life.

According the above embodiments, the battery measurement platform sets up the communication with the measured battery, determines the model of the measured battery, and searches data of the measured battery according to the model thereof to obtain the state-of-charge of the measured battery. Accordingly, the estimation of the state-of-charge of batteries is performed per-battery, instead of per-battery measurement platform. Thus, it is ensured accurate measurement, random battery change, and convenient maintaining.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is an exemplary embodiment of a flow chart of an estimation method for estimating a state-of-charge of batteries;

FIG. 2 is a schematic view showing an exemplary embodiment of a finding operation for data of a measured battery; and

FIG. 3 shows an exemplary embodiment of an estimation device for state-of-charge of batteries.

### DETAILED DESCRIPTION OF THE INVENTION

This description is made for the purpose of illustrating the general principles of the invention and should not be taken in a limiting sense. In addition, the present disclosure may repeat reference numerals and/or letters in the various examples. This repetition is for the purpose of simplicity and clarity and does not in itself dictate a relationship between the various embodiments and/or configurations discussed. The scope of the invention is best determined by reference to the appended claims.

It is understood that the following disclosure provides many different embodiments, or examples, for implementing different features of the application. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact.

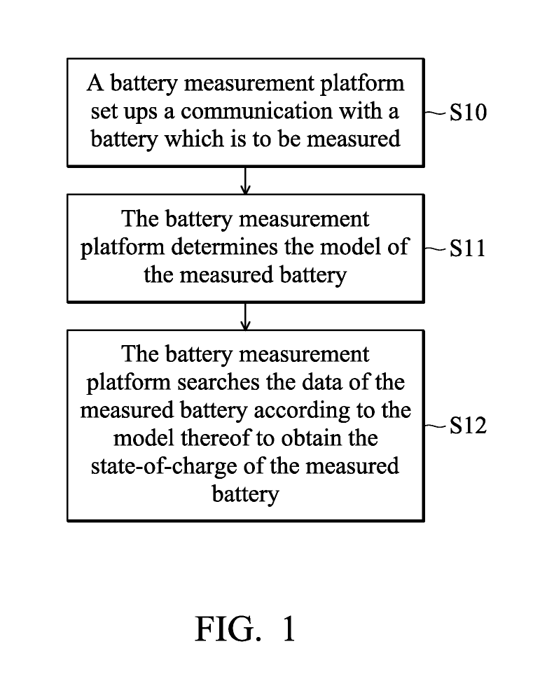

FIG. 1 is a flow chart of an estimation method for state-of-charge of batteries. As shown in FIG. 1, the estimation method for estimating a state-of-charge of batteries comprises:

Step S10: a battery measurement platform sets up a communication with a battery which is to be measured.

The measured battery can be a defaulted battery which is supported by the battery measurement platform, such that the battery measurement platform can detect the model and data automatically. In another embodiment, the measured battery is not a defaulted battery which is supported by the battery measurement platform. At this case the model and the data of the battery can be inputted by a user. During the initialization, an actual battery reference table is built according to the current definition of the battery measurement platform.

Step S11: the battery measurement platform determines the model of the measured battery.

Traditionally, a battery measurement platform is dedicated for a specific battery, and is built by a fixed coding module in the specific battery. For example. The battery data is tired with the battery measurement platform in the form of cust_battery_meter_table. In the embodiment, the battery measurement platform is designed that the battery date is departed from the predetermined coding module for building battery data profiles of the battery models, and builds the profiles in a specific catalog of a user spacer for access. For example, the access is achieved by an internet data center (IDC) of a touch screen of an input sub-system. For each model of batteries, the battery measurement platform builds an independent battery data profile and organizes a battery data profile for measurement reference according to the model of the battery. The battery measurement platform pre-defines a model table of the defaulted batteries which are supported by the battery measurement platform, and a battery, which is predetermined for the usage by the battery measurement platform, is disposed.

In the step S11, the battery measurement platform determines the model of the measured battery through an identification circuit. Specifically, the battery measurement platform checks the pre-defined model table of the defaulted supported batteries by the identification circuit according to a predetermined communication protocol to obtain the model of the measured battery. Particularly, the battery measurement platform comprises a battery identification and authentication integrated circuit. The battery identification and authentication integrated circuit has the token authentication function of the hardware secure hash algorithm (SHA-1), such that the system security is enhanced without the increment of the cost and complexity of the microprocessor systems. The battery identification and authentication integrated circuit connects a touch point of the battery through-Wire interface. Performing the series communication through the low voltage 1-Wire interface occupies only one touch point of the battery, such that the battery authentication function is accomplished. When the determination for the model of the measured battery automatically through the identification circuit is not successful, that is when the measured battery is not listed in the pre-defined model table of the defaulted batteries supported by the battery measurement platform, the model of the measured battery is received. In other words, in this case, the model of the measured battery is input manually by the user through the multimedia interface.

Step S12: the battery measurement platform searches the data of the measured battery according to the model thereof to obtain the state-of-charge of the measured battery.

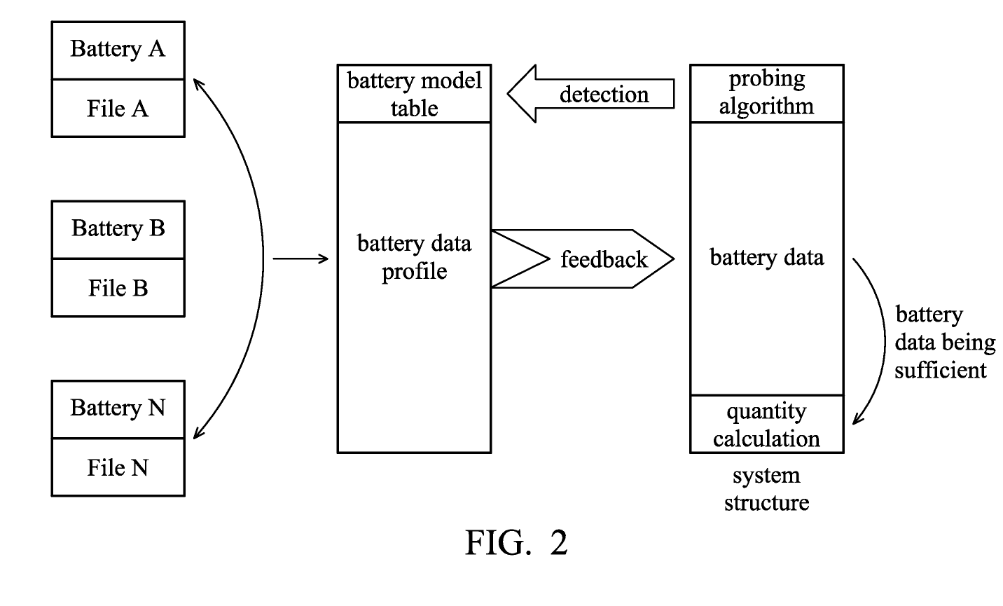

In the step S12, the data of the measured battery may be automatically found from the databased according to the model of the measured battery. That is, the battery measurement platform selects the data of the measured battery according to the model of the measured battery. In the embodiment, the battery measurement platform stores a defaulted supported battery table which includes a part of the models of the batteries supported by the battery measurement platform. The battery measurement platform also stores the battery data corresponding to the models of the batteries in the defaulted supported battery table. Each model has independent battery data which is stored in the corresponding battery data file. The battery data files of multi models form the database of the battery data. In the step S11, when the model of the measured battery is listed in the pre-defined model table of the defaulted supported batteries, the battery measurement platform automatically searches the corresponding battery data. As shown in FIG. 2, the battery measurement platform searches the model of the measured battery by the probing algorithm. When the model of the measured battery is identified from the pre-defined model table of the defaulted supported batteries (including Battery A-Battery N), for example Battery A, the battery data file of the measured battery is then found from the battery data profile, for example File A, to obtain the battery data. The obtained battery data is fed back to the battery measurement platform for performing the related calculation according to the sufficient battery data to obtain the state-of-charge of the measured battery. In the step S11, when the model of the measured battery is not listed in the pre-defined model table of the defaulted supported batteries, this is to say, the battery measurement platform does not store the corresponding battery data, the battery measurement platform obtains the data of the measured battery from the outside of the battery measurement platform. Specifically, if there is the data of the measured battery in the remote, such as a cloud system, the battery measurement platform obtains the data of the measured battery from the cloud system. More specifically, the user may add one selection term in the battery list of the setting of the battery measurement platform to obtain the data of the measured battery from the cloud system. The procedure of obtaining the data of the measured battery from the cloud system comprises sending a request of the data of the model of the measured battery and sending a response for the request. If there is no data of the measured battery in the remote, such as the cloud system, the user inputs technique parameters through the multimedia interface to obtain the corresponding accurate battery data. Preferably the input technique parameters can be the related technique parameters marked to the measured battery. Thus, the standard kernel interface of the battery measurement platform is not required to have the complete battery technique parameters. The battery measurement platform can accomplish the correct battery finding through an additional operation. For example, multimedia interface is provided for the battery switching. The selection terms in the battery list of the setting (setting->battery) can be increased for the dynamic selection in the model table of the defaulted batteries supported by the battery measurement platform and the rough filling of new battery data.

In the embodiment, the data of the measured battery is stored in the database and not dedicated to the battery measurement platform, that is, the data of the measured battery is not fixed at the battery measurement platform. The data of the measured battery is stored by a modifiable form. The database stores battery data related to at least two models. The battery data related to one of the at least two models stored in the database is received from the cloud system, or the battery data related to one of the at least two models stored in the database is input through the multimedia interface. Thus, the estimation method of estimating state-of-charge of batteries is performed per-battery. The fixed coding module in the current technique is replaced with dynamic reading manner. In other words, the estimating of state-of-charge of batteries is performed on the base of each battery, instead of on the base of each battery measurement platform. Only one experiment data is preserved for one model of the battery. Thus, the battery measurement platform can be used for the batteries with different models, and it is convenient to preserve the battery data. When it is desirable to change the battery, the user can achieve the battery change according to the pre-defined model table of the defaulted supported batteries without inaccurate measured result.

The data of the measured battery can be dynamically corrected and updated through the cloud system. Specifically, the corrected and updated data of the measured battery transmitted by the cloud system is continuously generated according to the practice data of the measured battery disposed in different loads. Since the battery data is updated continuously, it ensures that the estimation result is more accurate. In other words, for each battery model, the cloud system is capable of continuously receiving the battery data which is continuously updated and transmitted from mobile terminals. Accordingly, the battery data stored in the cloud system is updated continuously. Thus, the battery data loaded to the mobile terminal from the cloud system is more accurate, and the error between the actual data and the loaded data of the battery is less. The data of the measured battery comprises the model of the measured battery and the feature curve data matching the measured battery. The feature curve data comprises the mapping relationship between the internal resistance and voltage/temperature, the mapping relationship between the voltage and the capacity, the data variation between the additional data and cycle life. According to the obtained data of the measured battery, the state-of-charge is detected, and the actual consumed power of the measured battery can be obtained. Moreover, when the estimation method for the state of charge of batteries according to the invention is applied for calculating how much power is obtained when the battery is charged, the quantity of the increased power of the battery can be detected accurately. The user can be charged according to the actual quantity of the power which is consumed when the battery is charged. The actual quantity of the power of the measured battery can be uploaded to the individual account, and then the real-time payment can be performed accurately.

Thus, in the embodiment, the battery measurement platform sets up the communication with the measured battery, determines the model of the measured battery, and searches the data of the measured battery according to the model thereof to obtain the state-of-charge of the measured battery. It is ensured accurate measurement, random battery change, and convenient maintaining.

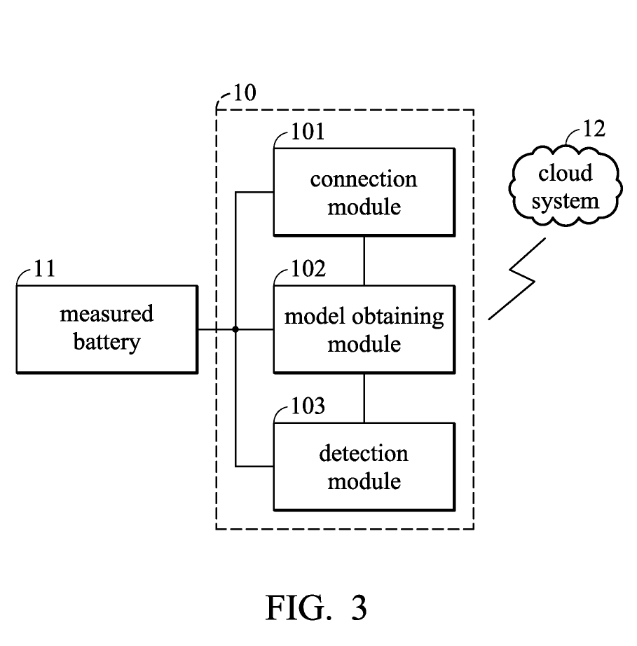

FIG. 3 shows an exemplary embodiment of an estimation device for state-of-charge of batteries. As shown in FIG. 3, the estimation device 10 comprises a connection module 101, a model obtaining module 102, and a detection module 103. The estimation device 10 is a part of a battery measurement platform (not shown). The connection module 101 is configured to make the battery measurement platform to set up a communication with a measured battery 11. The model obtaining module 102 is coupled to the connection module 101. The model obtaining module 102 is configured to make the battery measurement platform to determine the model of the measured battery. The detection module 103 is coupled to the model obtaining module 102. The detection module 103 is configured to make the battery measurement platform to search the data of the measured battery 11 for obtaining the state-of-charge of the measured battery 11.

In the embodiment, the measured battery can be a defaulted battery which is supported by the battery measurement platform. In another embodiment, the measured battery is not a defaulted battery which is supported by the battery measurement platform. At this case the model and the data of the battery can be inputted by a user. During the initialization of the estimation device 10, an actual battery reference table is built according to the current definition of the battery measurement platform. The battery measurement platform makes the battery date to depart from the predetermined coding module for building a battery data profiles of the specific battery models and build the profiles in a specific catalog of a user spacer for access. For example, the access is achieved by an internet data center (IDC) of a touch screen of an input sub-system. For each model of batteries, the battery measurement platform builds an independent battery data profile and organizes a battery data profile for measurement reference according to the model of the battery. The battery measurement platform pre-defines a model table of the defaulted batteries which are supported by the battery measurement platform, and a battery, which is predetermined for the usage by the battery measurement platform, is disposed.

The model obtaining module 102 determines the model of the measured battery through an identification circuit. When the determination for the model of the measured battery is not successful, that is when the measured battery is not listed in the pre-defined model table of the defaulted batteries supported by the battery measurement platform, the model of the measured battery is loaded. In other words, in this case, the model of the measured battery is input manually by the user through the multimedia interface.

The detection module 103 is capable of searching the data of the measured battery according to the model thereof determined by the model obtaining module 102 to obtain the state-of-charge of the measured battery. That is, the data of the measured battery is selected by the battery measurement platform according to the model of the measured battery determined by the model obtaining module 102. In the embodiment, the battery measurement platform stores a defaulted supported battery table which includes at least a part of the models of the batteries supported by the battery measurement platform. The battery measurement platform also stores the battery data corresponding to the models of the batteries in the defaulted supported battery table. Each different model has an independent battery data which is stored in the corresponding different battery data file. The battery data files of multi models form the database of the battery data. When the model obtaining module 102 determines that the model of the measured battery is listed in the pre-defined model table of the defaulted supported batteries, the battery measurement platform automatically finds the corresponding battery data. When the model obtaining module 102 determines that the model of the measured battery is not listed in the pre-defined model table of the defaulted supported batteries, the data of the measured battery is obtained from the remote or obtained by receiving the data input by the user. If there is the data of the measured battery in the remote, such as a cloud system, the data of the measured battery is obtained through the battery measurement platform. Specifically, the user may add one selection term in the battery list of the setting of the battery measurement platform, such that the user can obtain the data of the measured battery conveniently. If there is no data of the measured battery in the remote, such as a cloud system, the user inputs technique parameters according to the measured battery through the multimedia interface to obtain the corresponding relative accurate battery data. Preferably the input technique parameters can be the related technique parameters marked to the measured battery. Thus, the standard kernel interface of the battery measurement platform is not required to have the complete battery technique parameters. The correct battery finding can be accomplished through an additional operation. For example, multimedia interface is provided for the battery switching. The selection terms in the battery list of the setting (setting->battery) can be increased for the dynamic selection in the model table of the defaulted batteries supported by the battery measurement platform and the rough filling of new battery data.

In the embodiment, the data of the measured battery 11 is stored in the database and not dedicated to the battery measurement platform, that is, the data of the measured battery is not fixed at the battery measurement platform. The data of the measured battery is stored by a modifiable form. The database stores battery data related to at least two models. The battery data related to one of the at least two models stored in the database is received from the cloud system, or the battery data related to one of the at least two models stored in the database is input through the multimedia interface. Thus, the estimation method of state-of-charge of batteries is performed per-battery. The fixed coding module in the current technique is replaced with dynamic reading manner. In other words, the estimating of state-of-charge of batteries is performed on the base of each battery, instead of on the base of each battery measurement platform. Only one experiment data is preserved for one model of the battery. Thus, the battery measurement platform can be used for the batteries with different models, and it is convenient to preserve the battery data. When it is desirable to change the battery, the user can achieve the battery change according to the pre-defined model table of the defaulted supported batteries without inaccurate measured result.

The data of the measured battery can be dynamically corrected and updated through the cloud system. Specifically, the corrected and updated data of the measured battery transmitted by the cloud system is continuously generated according to the actual data of the measured battery in different loads. Since the battery data is updated continuously, it is ensured that the estimation result is more accurate. The data of the measured battery comprises the model of the measured battery and the feature curve data matching the measured battery. The feature curve data comprises the mapping relationship between the internal resistance and voltage/temperature, the mapping relationship between the voltage and the capacity, and the data variation between additional data and the cycle life. According to the obtained data of the measured battery, the state-of-charge is detected, and the actual consumed power of the measured battery can be obtained. The actual quantity of the power of the measured battery can be uploaded to the individual account, and then the real-time payment can be performed accurately.

As the above description, the battery measurement platform sets up the communication with the measured battery, determines the model of the measured battery, and searches the data of the measured battery according to the model thereof to obtain the state-of-charge of the measured battery. Accordingly, the estimation method of state-of-charge of batteries is performed in units of one battery. Thus, it is ensured accurate measurement, random battery change, and convenient maintaining.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An estimation method comprising:
setting up a communication with a measured battery by a battery measurement platform;
determining a model of the measured battery by the battery measurement platform; and
searching data of the measured battery according to the model of the measured battery by the battery measurement platform to obtain a state-of-charge of the measured battery.

2. The estimation method as claimed in claim 1, wherein the step of determining the model of the measured battery comprises:
determining the model of the measured battery through an identification circuit; and
receiving the model of the measured battery through a multimedia interface when determining the model of the measured battery through the identification circuit is not successful.

3. The estimation method as claimed in claim 1, wherein the step of searching data of the measured battery according to the model of the measured battery comprises:
automatically searching the data of the measured battery from a database according to the model of the measured battery.

4. The estimation method as claimed in claim 3, wherein the data of the measured battery is stored in the database and not dedicated to the battery measurement platform, and the database comprises data of batteries with at least two models.

5. The estimation method as claimed in claim 4, wherein the data of the batteries with one of the least two models is received from a cloud system.

6. The estimation method as claimed in claim 4, wherein the data of the batteries with one of the least two models is input through a multimedia interface.

7. The estimation method as claimed in claim 4, wherein the data of the measured battery is corrected and updated through a cloud system.

8. The estimation method as claimed in claim 7, wherein the corrected and updated data of the measured battery from the clod system is generated according to actual data of the measured battery in different loads.

9. The estimation method circuit as claimed in claim 1, wherein the data of the measured battery comprises the model of the measured battery and a feature curve data matching the measured battery, and the feature curve data comprises mapping relationship between internal resistance and voltage or temperature, mapping relationship between a voltage and capacity, and data variation between additional data and cycle life.

10. An estimation device in a battery measurement platform, comprising:
a connection module, configured to setting up a communication between the battery measurement platform and a measured battery;
a model obtaining module, coupled to the connection module, configured to determine a model of the measured battery; and
a detection module, coupled to the model obtaining module, configured to search data of the measured battery according to the model of the measured battery to obtain state-of-charge of the measured battery.

11. The estimation device as claimed in claim 10, wherein the model obtaining module determines the model of the measured battery through an identification circuit and receives the model of the measured battery through a multimedia interface when the model of the measured battery is determined through the identification circuit unsuccessful.

12. The estimation device as claimed in claim 10, wherein the detection module automatically searches the data of the measured battery from a database according to the model of the measured battery.

13. The estimation device as claimed in claim 12, wherein the data of the measured battery is stored in the database and not dedicated to the battery measurement platform, and the database comprises data of batteries with at least two models.

14. The estimation device as claimed in claim 13, wherein the data of the batteries with one of the least two models is received from a cloud system.

15. The estimation device as claimed in claim 13, wherein the data of the batteries with one of the least two models is input through a multimedia interface.

16. The estimation device as claimed in claim 13 further comprising:
an update module correcting and updating the data of the measured battery through a cloud system.

17. The estimation device as claimed in claim 16, wherein the corrected and updated data of the measured battery transmitted from the clod system is generated according to actual data of the measured battery in different loads.

18. The estimation device circuit as claimed in claim 10, wherein the data of the measured battery comprises the model of the measured battery and a feature curve data matching the measured battery, and the feature curve data comprises mapping relationship between internal resistance and voltage or temperature, mapping relationship between a voltage and capacity, and data variation between additional data and cycle life.
